(19) United States
(12) Patent Application Publication
(10) Pub. No.: US 2024/0422953 A1
(43) Pub. Date: Dec. 19, 2024

(54) ELECTRICAL SYSTEM WITH COOLING BY HEAT-TRANSFER FLUID

(71) Applicants: SAFRAN, Paris (FR); SAFRAN ELECTRICAL & POWER, Blagnac Cédex (FR)

(72) Inventors: Toni YOUSSEF, MOISSY-CRAMAYEL (FR); Donatien Henri Edouard MARTINEAU, MOISSY-CRAMAYEL (FR); Cyrille GAUTIER, MOISSY-CRAMAYEL (FR); Samir NEHME, MOISSY-CRAMAYEL (FR)

(73) Assignees: SAFRAN, Paris (FR); SAFRAN ELECTRICAL & POWER, Blagnac Cédex (FR)

(21) Appl. No.: 18/706,624

(22) PCT Filed: Nov. 2, 2022
(86) PCT No.: PCT/FR2022/052059

§ 371 Date: May 1, 2024

(30) Foreign Application Priority Data
Nov. 8, 2021 (FR) 2111811

(51) Int. Cl. H05K 7/20

(52) U.S. Cl. CPC H05K 7/20927; H05K 7/20254; H05K 7/20272; H05K 7/20409

(57) ABSTRACT

An electrical system includes an electrical power module with a heat sink provided with heat-dissipating projections. The system further includes a cold plate of a heat-transfer fluid box. The cold plate has cavities which are complementary to the projections so as to receive said projections. Liquid metal is inserted between the heat sink and the cold plate, at least between the projections and the cavities.

### TECHNICAL FIELD OF THE INVENTION

This invention relates to an electrical system with cooling by heat transfer liquid and a method for manufacturing such a system.

### TECHNOLOGICAL BACKGROUND

It is known to use a heat sink with heat dissipation projections to cool an electrical power module. The heat sink is attached, for example, by mechanical clamping, stirring or sintering. The heat sink can then close a channel of a cooling system using a heat transfer fluid, generally a liquid such as water, so that the projections extend into the channel and are cooled by contact with the fluid circulating in the channel.

One problem with these cooling techniques is that they require the heat transfer fluid to be drained for installation and maintenance of the power module.

It may therefore be desirable to provide an electrical system that avoids at least some of the above problems and constraints.

The documents DE 100 39 770 A1 and U.S. Pat. No. 5,083,373 each describe a heat sink and a cold plate with complementary shapes.

The document DE 10 2019 200 011 A1 describes a heat sink with fins.

### SUMMARY OF THE INVENTION

An aircraft electrical system is therefore proposed, comprising:
an electrical power module comprising a heat sink provided with thermal dissipation projections; and
a cold plate of a heat transfer fluid box, having cavities complementary to the projections for receiving the latter;
   characterised in that the liquid metal is interposed between the heat sink and the cold plate, at least between the projections and the cavities.

The invention thus makes it easy to separate the power module from the heat transfer fluid box, as the power module is received on the cold plate and does not extend into the heat transfer fluid box. In addition, this easy separation is made possible while maintaining good heat exchange performance thanks to the cavities provided in the cold plate to accommodate the projections of the heat sink.

The liquid metal improves heat exchange and makes it easier to apply. Because it is liquid, it spreads naturally in the gap between the heat sink and the cold plate, despite its irregular shape due to the interlocking projections in the cavities.

Optionally, the liquid metal has a thermal conductivity greater than 50 W/m·K. This ensures good heat exchange.

Also optionally, the liquid metal remains liquid between −20° C. and 150° C. The liquid metal is therefore well suited to the environment of an aircraft, in which the temperatures in this range are generally encountered.

Also optionally, the projections have a height of at least 1 mm, preferably at least 2 mm. As a result, heat exchange is enhanced.

Also optionally, the projections can also comprise of fins and/or pins. These projections have complementary shapes that are easy to create in the cold plate.

Also optionally, the projections can also be produced by additive manufacturing. This manufacturing method is simple to implement and is particularly suitable for the manufacture of fins and/or pins.

Also optionally, the electrical power module comprises a substrate comprising an insulating plate and, on a lower face of the insulating plate, a lower layer forming at least in part the heat sink.

Also optionally, the electrical system further comprises:
a hydraulic pump;
a forward channel from the hydraulic pump to an inlet of the water box; and
a return channel from an outlet of the water box to the hydraulic pump.

Also proposed is an aircraft comprising an electrical system according to the invention.

Also proposed is a method for manufacturing an electrical system according to the invention, comprising:
partial filling of cavities with liquid metal; and
inserting the projections into the cavities, so that the projections push the liquid metal upwards into the cavities, preferably out so as to fill a gap between the heat sink and the cold plate outside the cavities and the projections.

### BRIEF DESCRIPTION OF THE FIGURES

The invention will be better understood with the aid of the following description, given only by way of example and made with reference to the attached drawings in which:

FIG. 1 is a cross-sectional view of an electrical system according to the invention,

FIG. 2 is a block diagram of a manufacturing method for an electrical system such as that shown in FIG. 1,

FIG. 3 is a view similar to FIG. 1, illustrating an intermediate manufacturing step,

FIG. 4 is a view similar to FIG. 1, illustrating an intermediate manufacturing step, and

FIG. 5 is a photograph of different types of projections that can be used.

### DETAILED DESCRIPTION OF THE INVENTION

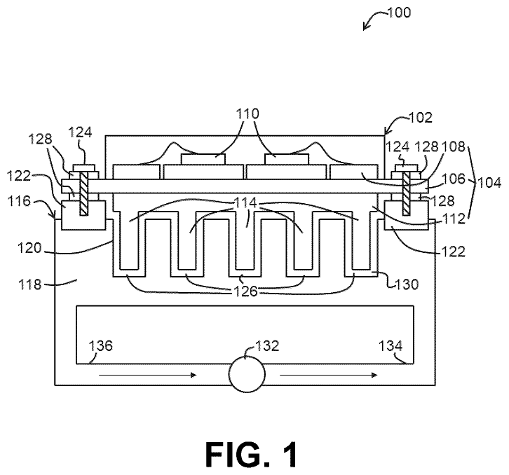

With reference to FIG. 1, an example of an aircraft electrical system 100, in which the invention is implemented, will now be described.

The electrical system 100 firstly comprises an electrical power module 102.

The electrical power module 102 comprises a substrate 104 comprising, for example, an electrically insulating intermediate plate 106 and an electrically conductive top layer 108 extending over an upper face of the intermediate plate 106.

The electrical power module 102 comprises at least one electrical part 110 mounted on the top layer 108 of the substrate 104. Each electrical part 110 is thus mechanically supported by this upper layer 108 and electrically connected to this upper layer 108.

The electrical power module 102 also comprises a heat sink 112, generally made of electrically conductive metal, extending over a lower face of the intermediate plate 106.

For example, the substrate 104 can be Direct Bonded Copper (DBC). In this case, the intermediate plate 106 is made of ceramic, while the upper layer 108 is made of copper, as is a lower layer forming at least part of the heat sink 112.

Alternatively, the heat sink could be formed by a base plate, for example made of copper or aluminium, attached to the substrate 104, for example to the bottom copper layer in the case of a DBC substrate.

The heat sink 112 has thermal dissipation projections 114, such as fins or pins, projecting downwards. Preferably, these projections 114 are made by additive manufacturing from an initial plate of the heat sink 112, for example as described in the international application published under number WO 2020 021197 A1.

This initial plate comprises, for example, the lower copper layer in the case of a DBC substrate. Manufacturing the projections 114 directly on the lower layer of the substrate 104 reduces thermal resistance and therefore increases thermal performance.

The projections 114 have a height of at least 1 mm, preferably at least 2 mm, and up to 2 cm or more.

The electrical system 100 also comprises a cooling system 116 of the electrical power module 102. The cooling system 116 uses a heat transfer fluid, preferably a heat transfer liquid. In the rest of the description, this heat transfer fluid is described as water, but other heat transfer fluids could be used.

The cooling system 116 comprises a water box 118 with a so-called cold plate 120 cooled by the water circulating in the water box 118. The cold plate 120 is designed to accommodate the power module 102. To achieve this, the cold plate 120 has, for example, brackets 122 for receiving the substrate 104, for example the intermediate plate 106. The power module 102, for example, is attached to the cold plate 120 by means of fastening screws 124, for example passing through the intermediate plate 106 and the brackets 122.

To promote heat dissipation, the cold plate 120 has cavities 126 which are complementary to the projections 114. Thus, once the power module 102 is mounted on the cold plate 120, the heat sink 112 is opposite the cold plate 120, with the projections 114 received in the cavities 126. This greatly increases the heat exchange surface area.

A gap is also provided between the power module 102 mounted on the cooling system 116 and the cold plate 120. In particular, the gap is present between the heat sink 112 and the cold plate 120, in particular at the cavities 126 and the projections 114. The gap is preferably greater than 100 μm and/or preferably less than 1 mm, in particular between the cavities 126 and the projections 114.

To seal the gap, seals 128 are provided, for example, in particular between the brackets 122 and the intermediate plate 106 and/or between the intermediate plate 106 and the heads of the fastening screws 124. These seals 128 also absorb the deformations of the liquid metal 130 as it expands and compresses with temperature.

To improve the heat conduction between the heat sink 112 (and in particular the projections 114) and the cold plate 120, the electrical system 100 also comprises the liquid metal 130 filling the gap, preferably completely to prevent air bubbles from forming. In fact, the latter could degrade the performance of the heat exchange. In particular, the liquid metal 130 is present between the projections 114 and the cavities 122 receiving them.

The liquid metal 130 preferably has good thermal conductivity, for example greater than 50 W/m·K. The liquid metal 130 preferably remains liquid between −20° C. and 150° C., which corresponds to the usual operating temperature range of an aircraft. The liquid metal 130, for example, has a dynamic viscosity of at least 1 mPa·s at 20° C.

An example of a liquid metal is Galinstan (Gallium-Indium-Stannum), made from an alloy of gallium, indium and tin. Galinstan is a liquid metal at room temperature. Its melting point is −19° C. In addition, Galinstan has a thermal conductivity of 73 W/m·K, much higher than that of traditional thermal interfaces (5 W/m·K), and its dynamic viscosity is 2.4 mPa·s at 20° C.

Other liquid metals may be suitable. Gallium, indium and tin alloys can be used, with different proportions of the elements, pure gallium or gallium-tin alloys.

To avoid any reaction between the liquid metal 130 and the heat sink 112, which is preferably made of copper or aluminium, as gallium is highly reactive with aluminium, it is advantageous to nickel plating of the heat sink 112, typically by electrochemical deposition.

To ensure circulation of the heat transfer fluid, water for example, in the heat transfer fluid box 118 and in particular in contact with the cold plate 120, the cooling system 116 also comprises a circuit, for example a sealed circuit, for circulation of the heat transfer fluid. This circuit typically comprises a hydraulic pump 132, a forward channel 134 from the hydraulic pump 132 to an inlet of the water box 118 and a return channel 136 from an outlet of the water box 118 to the hydraulic pump 132.

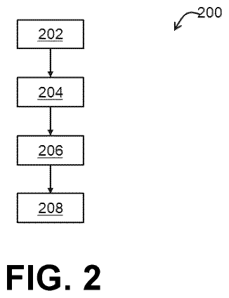

With reference to FIGS. 2 to 4, an example of a method 200 for manufacturing an electrical system such as that shown in FIG. 1 will now be described.

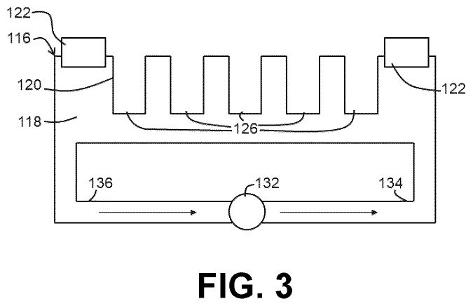

During a step 202, the cooling system 116 with the cold plate 120 according to the invention is obtained. The result of this step is shown in FIG. 3, for example.

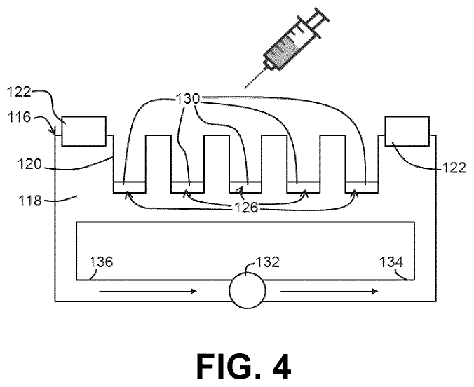

In step 204, the cavities 126 in the cold plate 120 are partially filled with the liquid metal 130. A few drops are usually enough. The result of this step is shown in FIG. 4, for example.

In a step 206, a power module, such as the power module 102 shown in FIG. 1, is mounted on the cooling system 116. During this stage, the projections 114 enter the cavities 126 and push the liquid metal up into the cavities and out of the cavities, so that it fills the gap. Advantageously, it is ensured that the volume of the gap is completely filled so as to guarantee optimum thermal cooling properties, by providing a volume of liquid metal greater than the volume of the gap. Knowing the volume of the gap, it is easy to dose the appropriate volume of liquid metal to be injected into the cavities 126 during step 204, typically using a graduated syringe.

In a step 208, the power module 102 is attached to the cooling system 116, for example by means of the fastening screws 124. The result of this step is, for example, the electrical system 100 shown in FIG. 1.

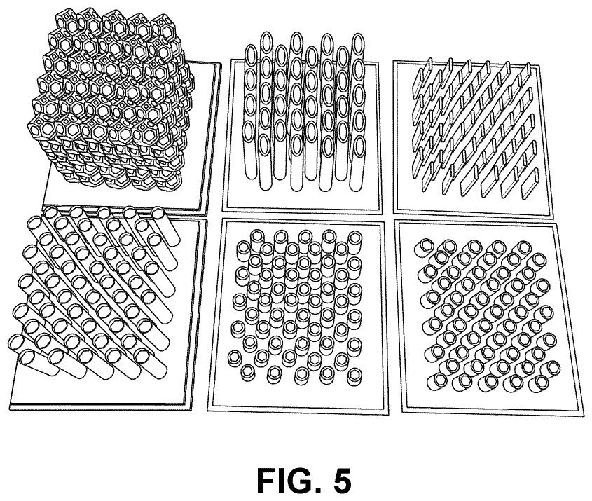

FIG. 5 shows the different shapes that the projections 114 can take.

In conclusion, it is clear that an electrical system such as that described above allows to assemble a power module to be cooled, on a cold plate, which is completely sealed and does not require purging of the cooling system. This is particularly advantageous when the power module is used in an aircraft, where the increasing integration of power electronics makes it difficult to dismantle the cooling system.

It will be further noted that the invention is not limited to the embodiments described above. Indeed, it will be apparent to the person skilled in the art that various modifications can be made to the above-described embodiments, in the light of the teaching just disclosed.

In the detailed presentation of the invention given above, the terms used should not be interpreted as limiting the invention to the embodiments set out in the present description, but should be interpreted to include all equivalents the anticipation of which is within the reach of the person skilled in the art by applying his general knowledge to the implementation of the teaching just disclosed.

1. An electrical system for an aircraft, comprising:
an electrical power module comprising a heat sink provided with thermal dissipation projections; and
a cold plate of a heat transfer fluid box, having cavities complementary to the projections for receiving the latter;
wherein liquid metal is interposed between the heat sink and the cold plate, at least between the projections and the cavities.

2. The electrical system of claim 1, wherein the liquid metal has a thermal conductivity greater than 50 W/m·K.

3. The electrical system according to claim 1, wherein the liquid metal remains liquid between −20° C. and 150° C.

4. The electrical system according to claim 1, wherein the projections have a height of at least 1 mm.

5. The electrical system according to claim 1, wherein the projections comprise fins and/or pins.

6. The electrical system according to claim 1, wherein the projections are made by additive manufacturing.

7. The electrical system according to claim 1, wherein the electrical power module comprises a substrate that includes an insulating plate and, on a lower face of the insulating plate (106), a lower layer forming at least in part the heat sink (112).

8. The electrical system according to claim 1, further comprising:
a hydraulic pump;
a forward channel from the hydraulic pump to an inlet of the water box; and
a return channel from an outlet of the water box to the hydraulic pump.

9. An aircraft comprising an electrical system according to claim 1.

10. A method (200) of manufacturing the electrical system (100) according to claim 1, the method comprising the steps of:
partial filling of the cavities with liquid metal; and
inserting the projections into the cavities, so that the projections push the liquid metal upwards into the cavities.

11. The method of claim 9, wherein the step of inserting the projections into the cavities fills a gap between the heat sink and the cold plate outside the cavities and the projections with the liquid metal.

12. The electrical system according to claim 4, wherein the projections have a height of at least 2 mm.
